(19) United States
(12) Patent Application Publication
(10) Pub. No.: US 2011/0255247 A1
(43) Pub. Date: Oct. 20, 2011

(54) HEAT SINK ASSEMBLY AND ELECTRONIC DEVICE EMPLOYING THE SAME

(75) Inventor: Chung-Jun CHU, Tu-Cheng (TW)

(73) Assignee: HON HAI PRECISION INDUSTRY CO., LTD., Tu-Cheng (TW)

(21) Appl. No.: 12/853,280

(22) Filed: Aug. 9, 2010

(30) Foreign Application Priority Data
Apr. 15, 2010 (CN) 201020160384.0

(51) Int. Cl. H05K 7/20

(52) U.S. Cl. 361/709

(57) ABSTRACT

A heat sink assembly with shielding frame is mounted on a circuit board and includes a heat sink, a shielding frame and a heat transmitting film. The circuit board comprises at least one electronic component and a plurality of latching slots surrounding the electronic component. The heat sink includes a base and a plurality of heat fins extending upwardly from the base. A plurality of slots are defined between the plurality of heat fins. The shielding frame includes a hollow frame, a plurality of latch portions and a plurality of limitation portions. The plurality of latch portions are disposed on one end of the hollow frame and evenly spaced apart from each other. The plurality of limitation portions extend from the other end of the hollow frame. The shielding frame cooperates with the heat sink to shield the electronic component from electromagnetic interference (EMI).

### BACKGROUND

1. Technical Field

The present disclosure relates to an electronic device, and more particularly to a heat sink assembly for the electronic device.

2. Description of Related Art

With the rapid development of technology, the speed of chipsets, such as central processing units (CPUs), on an integrated circuit board has increased. Because the integrated circuit board generally comprises high frequency circuits, digital signal circuits and analog signal circuits, electromagnetic interference (EMI) often occurs between neighboring electronic components due to inductive coupling. In addition, the increased speed of the chipsets increases EMI levels. A heat sink assembly can be mounted on the integrated circuit board and comprises a plurality of heat fins to dissipate heat generated by the electronic components. However, the heat sink assembly does not shield the electronic components from external EMI. Therefore, the effective performance of the electronic components may be disrupted, obstructed, or degraded by EMI.

Therefore, a need exists in the industry to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a disassembled perspective view of one embodiment of a heat sink assembly in accordance with the present disclosure.

FIG. 2 is another disassembled perspective view of the embodiment of the heat sink assembly in accordance with the present disclosure, showing the heat sink assembly disposed on a chipset.

FIG. 3 is an assembled view of the embodiment of the heat sink assembly in accordance with the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

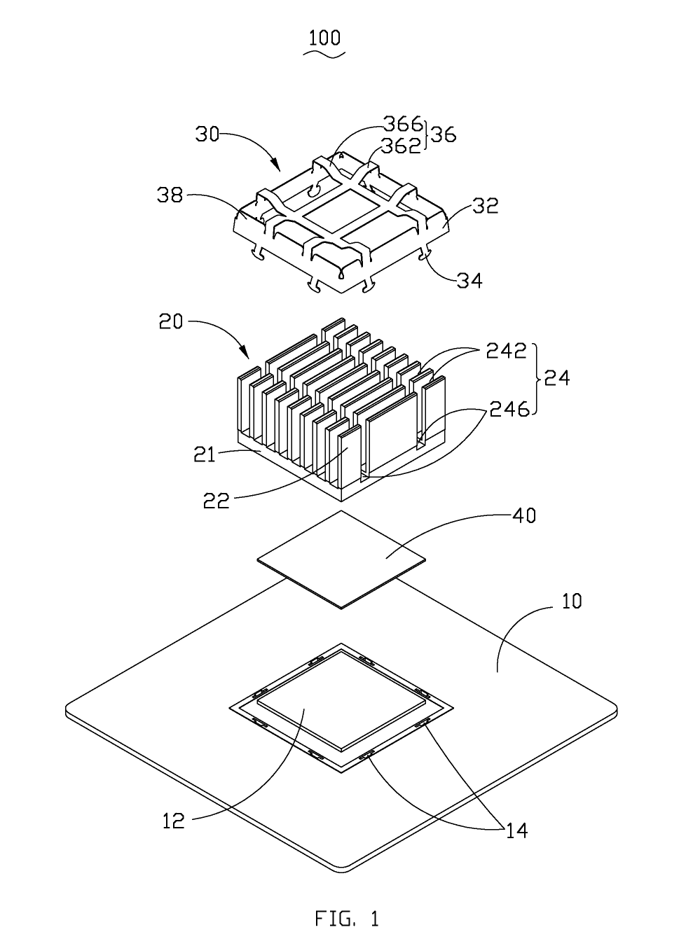

FIG. 1 is a disassembled perspective view of a heat sink assembly 100 in accordance with the present disclosure. The heat sink assembly 100 is mounted on a circuit board 10, such as a printed circuit board. The heat sink assembly 100 comprises a heat sink 20, a shielding frame 30 and a heat transmitting film 40.

The circuit board 10 comprises at least one electronic component 12 and a plurality of latching slots 14 in four rows surrounding the electronic component 12. The section of the latching slot 14 is T-shaped.

The heat sink 20 comprises a base 21 and a plurality of heat fins 22 extending upwardly from the base 21. The plurality of heat fins 22 are integrally formed with the base 21 and arranged in rows and columns. A plurality of slots 24 are defined between the plurality of heat fins 22. The plurality of slots 24 comprise a plurality of first slots 242 parallel with each other and at least one second slot 246 intersecting the plurality of first slots 242. In the illustrated embodiment, the plurality of slots 24 comprise two second slots 246.

Alternatively, the heat fins 22 may be heat pins, heat dissipating protuberances, heat plates, or other heat dissipating structures known in the art.

The shielding frame 30 comprises a hollow frame 32, a plurality of latch portions 34, a plurality of limitation portions 36 and a plurality of spring clips 38. In the illustrated embodiment, the shielding frame 30 is made of metal. The plurality of latch portions 34 are disposed on one end of the hollow frame 32 and evenly spaced apart from each other. The plurality of latch portions 34 are integrally formed with the hollow frame 32 and have flexible performance. The plurality of limitation portions 36 and the plurality of spring clips 38 extend from the other end of the hollow frame 32. The plurality of limitation portions 36 comprise at least one first limitation strap 362 and at least one second limitation strap 366 perpendicular to the at least one first limitation strap 362. The first limitation strap 362 and the second limitation strap 366 are received in corresponding first slot 242 and second slot 246 to engage the shielding frame 30 with the heat sink 20. The plurality of spring clips 38 are extended from the hollow frame 32 towards the limitation portion 36 to engage with the heat sink 20, thereby improving EMI shielding performance.

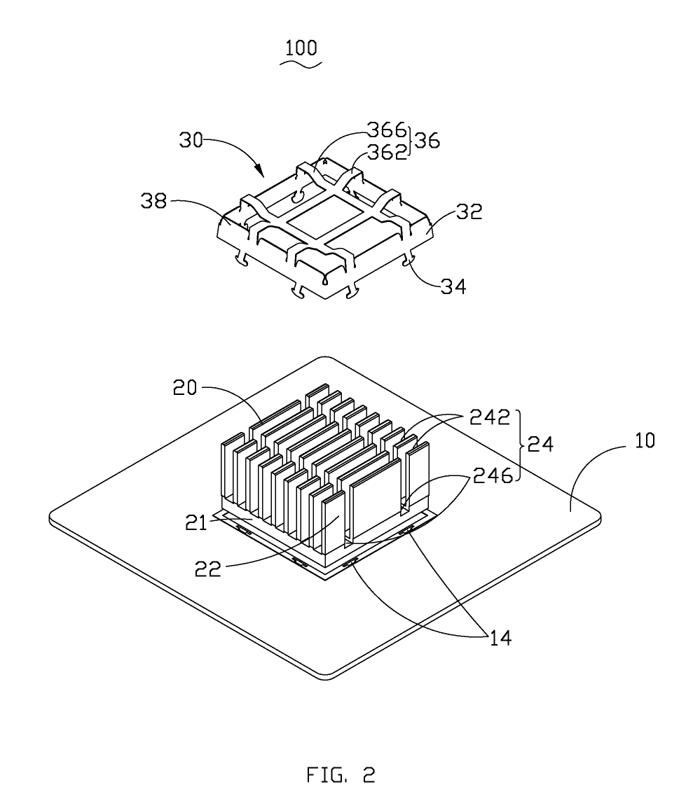

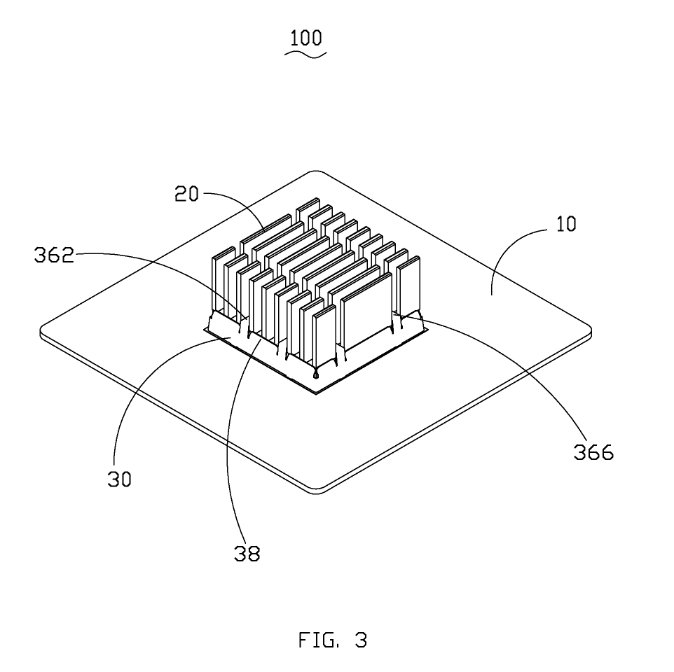

Referring to FIG. 2 and FIG. 3, in assembly, the heat transmitting film 40 is attached to the heat sink 20 to transmit heat from the electronic component 12 to the heat sink 20. The base 21 of the heat sink 20 is disposed on the electronic component 12. The plurality of latching slots 14 surround the heat sink 20 in four rows. The shielding frame 30 is attached to the heat sink 20 via inserting the plurality of limitation portions 36 into the corresponding slot 24. Each of the plurality of latch portions 34 of the shielding frame 30 is inserted into the corresponding latching slot 14 of the circuit board 10. Thus, the heat sink 20, the shielding frame 30 and the heat transmitting film 40 are assembled. The shielding frame 30 is shielded the heat sink 20 above the electronic component 12. The plurality of spring clips 38 are resisted on the heat sink 20 so that the shielding frame 30 cooperates with the heat sink 20 to shield the electronic component 12 from EMI.

The plurality of latch portions 34 are inserted into the plurality of the latching slots 14 to install the shielding frame 30 onto the circuit board 10. In disassembly, the plurality of latch portions 34 can be disassembled from the plurality of latching slots 14 by exerting an outside force on the plurality of latch portions 34, so that the shielding frame 30 is removed from the circuit board 10.

Because the heat sink assembly 100 comprises the shielding frame 30 and the heat sink 20, the heat sink assembly 100 not only protects the electronic component 12 from EMI, but also effectively dissipates heat generated by the electronic component 12.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A heat sink assembly, mounted on a circuit board comprising at least one electronic component and a plurality of latching slots surrounding the electronic component, the heat sink assembly comprising:
a heat sink, comprising a base and a plurality of heat fins extending upwardly from the base, wherein a plurality of slots are defined between the plurality of heat fins;
a heat transmitting film, attached to the heat sink to transmit heat from the electronic component to the heat sink; and
a shielding frame, comprising a hollow frame, a plurality of latch portions and a plurality of limitation portions, the plurality of latch portions disposed on one end of the hollow frame and evenly spaced apart from each other, the plurality of limitation portions extending from the other end of the hollow frame;
wherein the shielding frame is attached to the heat sink via inserting the plurality of limitation portions into the corresponding slots, each of the plurality of latch portions is inserted into the corresponding latching slot to install the shielding frame to the circuit board, the shielding frame cooperates with the heat sink to shield the electronic component from electromagnetic interference (EMI).

2. The heat sink assembly as claimed in claim 1, wherein the section of the latching slot is T-shaped.

3. The heat sink assembly as claimed in claim 2, wherein the plurality of slots comprise a plurality of first slots parallel with each other and at least one second slot intersecting the plurality of first slots.

4. The heat sink assembly as claimed in claim 3, wherein the plurality of limitation portions comprise at least one first limitation strap and at least one second limitation strap perpendicular to the at least one first limitation strap, the first limitation strap and the second limitation strap are received in corresponding first slot and second slot to engage the shielding frame with the heat sink.

5. The heat sink assembly as claimed in claim 4, wherein the shielding frame further comprises a plurality of spring clips, the plurality of spring clips are extended from the hollow frame towards the heat sink and resisted on the heat sink so that the shielding frame cooperates with the heat sink to shield the electronic component from the EMI.

6. An electronic device, comprising:
a circuit board, comprising an electronic component and a plurality of latching slots surrounding the electronic component; and
a heat sink assembly with shielding frame, mounted on the circuit board, comprising:
a heat sink, comprising a base and a plurality of heat fins extending upwardly from the base, a plurality of slots formed between the plurality of heat fins; and
a shielding frame, comprising a hollow frame, a plurality of latch portions and a plurality of limitation portions, the plurality of latch portions disposed on one end of the hollow frame and evenly spaced apart from each other, the plurality of limitation portion extending from the other end of the hollow frame;
wherein the shielding frame is placed over the heat sink via inserting the plurality of limitation portions into the corresponding slot, each of the plurality of latch portions is inserted into the corresponding latching slot to install the shielding frame to the circuit board, the shielding frame cooperates with the heat sink to shield the electronic component from electromagnetic interference (EMI).

7. The electronic device as claimed in claim 6, wherein the heat sink assembly further comprises a heat transmitting film attached to the heat sink to transmit heat from the electronic component to the heat sink.

8. The electronic device as claimed in claim 7, wherein the section of the latching slot is T-shaped.

9. The electronic device as claimed in claim 8, wherein the plurality of slots comprise a plurality of first slots parallel with each other and at least one second slot intersecting the plurality of first slots.

10. The electronic device as claimed in claim 9, wherein the plurality of limitation portions comprise at least one first limitation strap and at least one second limitation strap perpendicular to the at least one first limitation strap, the first limitation strap and the second limitation strap are received in corresponding first slot and second slot to engage the shielding frame with the heat sink.

11. The electronic device as claimed in claim 10, wherein the shielding frame further comprises a plurality of spring clips, the plurality of spring clips are extended from the hollow frame towards the heat sink and resisted on the heat sink so that the shielding frame cooperates with the heat sink to shield the electronic component from EMI.
